(19) United States
(12) Patent Application Publication
(10) Pub. No.: US 2023/0329127 A1
(43) Pub. Date: Oct. 12, 2023

(54) RESISTIVE MEMORY DEVICE AND METHOD OF FORMING

(71) Applicants: Tokyo Electron Limited, Tokyo (JP); INTERNATIONAL BUSINESS MACHINES CORPORATION, Armonk, NY (US)

(72) Inventors: Devi Koty, Hopewell Junction, NY (US); Qingyun Yang, Hopewell Junction, NY (US); Hiroyuki Miyazoe, Hopewell Junction, NY (US); Takashi Ando, Hopewell Junction, NY (US)

(21) Appl. No.: 18/188,819

(22) Filed: Mar. 23, 2023

Related U.S. Application Data
(60) Provisional application No. 63/323,971, filed on Mar. 25, 2022.

(51) Int. Cl. H10N 70/20; H10N 70/00

(52) U.S. Cl. CPC H10N 70/063; H10N 70/24; H10N 70/841; H10N 70/8833

(57) ABSTRACT

A resistive memory device with an embedded shoulder pulled sidewall spacer and method of forming. The method includes providing a patterned film stack containing a lower electrode layer, a dielectric filament layer on the lower electrode layer, and an upper electrode layer on the dielectric filament layer, depositing a conformal cap layer on the patterned film stack, dry etching the conformal cap layer to form a sidewall spacer on sidewalls of the patterned film stack, where a top of the sidewall spacer is recessed to below a top of the upper electrode layer by the dry etching. The method further includes encapsulating the patterned film stack in an isolation layer, and etching the isolation layer to expose the upper electrode layer without exposing the sidewall spacer.

### CROSS-REFERENCE TO RELATED APPLICATIONS

This application is related to and claims priority to United States Provisional Patent Application serial no. 63/323,971 filed on Mar. 25, 2022, the entire contents of which are herein incorporated by reference.

### FIELD OF THE INVENTION

This invention relates to resistive memory devices, and more particularly, to a resistive memory device with an embedded shoulder pulled sidewall spacer and method of forming.

### BACKGROUND OF THE INVENTION

Resistive random access memory (ReRAM) is considered a promising technology for electronic synapse devices or memristor for neuromorphic computing as well as high-density and high-speed non-volatile memory applications. In neuromorphic computing applications, a resistive memory device can be used as a connection (synapse) between a pre-neuron and a post-neuron, representing the connection weight in the form of device resistance. Multiple pre-neurons and post-neurons can be connected through a crossbar array of ReRAMs, which naturally expresses a fully-connected neural network.

Oxygen vacancies in a dielectric layer are the building blocks of a current conducting filament in a ReRAM device. Therefore, ReRAM devices need to be formed with a predetermined amount of oxygen vacancies, without introducing damages to the perimeter of devices. Further, the ReRAM devices need to be protected to prevent oxygen penetration into the dielectric layer during the manufacturing process. These issues are not trivial and they often limit the scalability of ReRAM devices.

FIGS. 1A-1E schematically show through side cross-sectional views a process flow for a known method of manufacturing a resistive memory device. FIG. 1A shows an exemplary film stack 100 that contains a base layer 105, a bottom electrode layer 110, a dielectric filament layer 115 that serves as the conducting filament in the device, a upper electrode layer 120 containing a metal nitride laminate, and a hard mask layer 125.

The film stack 100 undergoes processing that includes film patterning using a mask pattern and an etching process that anisotropically etches the film stack 100 and stops on the bottom electrode layer 110. Thereafter, a cap layer 130 is conformally deposited over the exposed surfaces of the patterned film stack 101, including on the hard mask layer 125, on the sidewalls of the etched features, and on the bottom electrode layer 110 between the etched features. The resulting structure is schematically shown in FIG. 1B. The cap layer 130 conformally covers the film stack 100 and serves, in part, to preserve the level of oxygen vacancies in the film stack materials, in particular in the dielectric filament layer 115, and to avoid electrical shortage in the finished resistive memory device.

FIG. 1C shows the patterned film stack 101 following further processing that includes a planarization process, for example chemical mechanical planarization (CMP), that removes the horizontal portions of the cap layer 130 and the hard mask layer 125. The CMP process exposes the upper electrode layer 120. Although not shown in FIG. 1C, the CMP process produces contaminants and etch residues on exposed surfaces of the patterned film stack 101. Following the CMP process, those contaminants and etch residues must be removed before depositing additional layers on the film stack 100.

FIG. 1D shows the patterned film stack following a conventional wet cleaning process that removes the CMP contaminants and residues from the patterned film stack 101. The wet cleaning process can include diluted hydrofluoric acid (dHF) that is spun onto the substrate. A drawback of the wet cleaning process is that the patterned film stack 101 may be damaged due to inadequate etch resistivity of the cap layer 130 in dHF. In particular, the etch resistance of the cap layer 130 to dHF on the sidewalls of the film stack 100 is often worse than in other areas. This inadequate etch resistivity during the wet cleaning process can cause partial removal or damage of the cap layer 130 on the sidewalls and/or result in surface roughness damage of the materials exposed to the chemicals used in the wet cleaning process. This can generate a damaged area 140 on the upper portion of the sidewalls and possibly damage the lower portion of the cap layer 130. The extend of the damage can vary between isolated and nested areas. This can result in unwanted oxidation of materials in the film stack 100 by oxygen-containing species that are the present in the wet cleaning process and/or during exposure to air.

FIG. 1E shows the film stack 100 following further processing that includes depositing a dielectric film 145, followed by a contact etch that forms a recessed feature in the dielectric film and connects to the upper electrode layer 120. Thereafter, the recessed feature is filled with a contact metal 150. As schematically shown in the figure, the contact metal 150 may fill a void 155 in the damaged area 140. This can result in an electrical short in the device and unwanted oxidation of the film stack, including the dielectric filament layer 115 that serves as the conducting filament in the device.

Therefore, new methods are needed that address these and others issues in manufacturing of resistive memory devices.

### SUMMARY OF THE INVENTION

A resistive memory device with an embedded shoulder pulled sidewall spacer and method of forming are described in several embodiments. In one example, the resistive memory device can include a ReRAM device.

According to one embodiment, the method includes providing a patterned film stack containing a lower electrode layer, a dielectric filament layer on the lower electrode layer, and an upper electrode layer on the dielectric filament layer, depositing a conformal cap layer on the patterned film stack, dry etching the conformal cap layer to form a sidewall spacer on sidewalls of the patterned film stack, where a top of the sidewall spacer is recessed to below a top of the upper electrode layer by the dry etching. The method further includes encapsulating the patterned film stack in an isolation layer, and etching the isolation layer to expose the upper electrode layer without exposing the sidewall spacer.

According to one embodiment, a resistive memory device includes a patterned film stack containing a lower electrode layer, a dielectric filament layer on the lower electrode layer, and an upper electrode layer on the dielectric filament layer, and a sidewall spacer on sidewalls of the patterned film stack, where a top of the sidewall spacer is recessed to below a top of the upper electrode layer. The resistive memory device further includes an isolation layer that encapsulates the upper electrode layer and the sidewall spacer, and a metal electrode layer in direct physical contact with the upper electrode layer, where the metal electrode layer is not in direct physical contact with the sidewall spacer.

### BRIEF DESCRIPTION OF THE DRAWINGS

FIGS. 1A-1E schematically show through side cross-sectional views a process flow for a known method of manufacturing a resistive memory device;

FIGS. 2A — 2G schematically show through side cross-sectional views a process flow for manufacturing a resistive memory device according to an embodiment of the invention;

FIG. 3 is a process flow diagram for manufacturing a resistive memory device according to an embodiment of the invention;

FIGS. 4A — 4C schematically show through side cross-sectional views a process flow for manufacturing a resistive memory device according to an embodiment of the invention; and

FIGS. 5A and 5B show experimental results for forming a sidewall spacer with different shoulder pulldown according to embodiments of the invention.

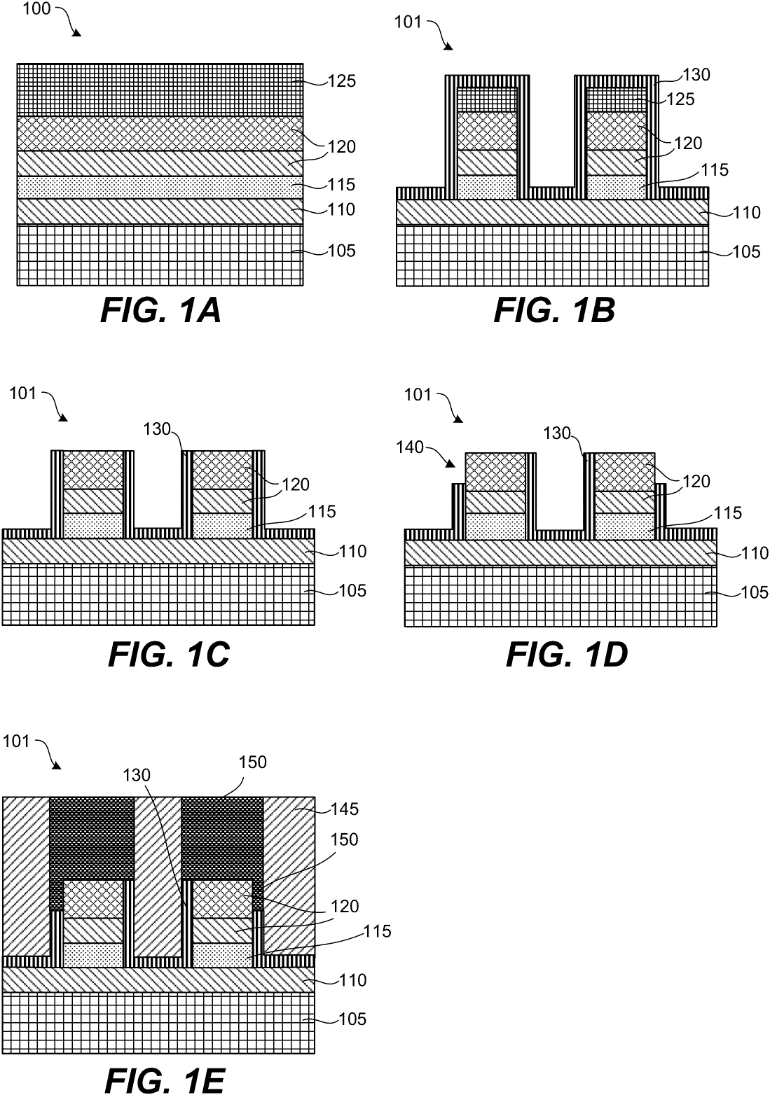

### DETAILED DESCRIPTION OF SEVERAL EMBODIMENTS

Embodiments of the invention describe a resistive memory device and method of forming. According to one embodiment, the resistive memory device includes an embedded shoulder pulled sidewall spacer. The sidewall spacer reduces etch damage to material layers in the device and reduces oxygen penetration into a dielectric filament layer that serves as the conducting filament in the device.

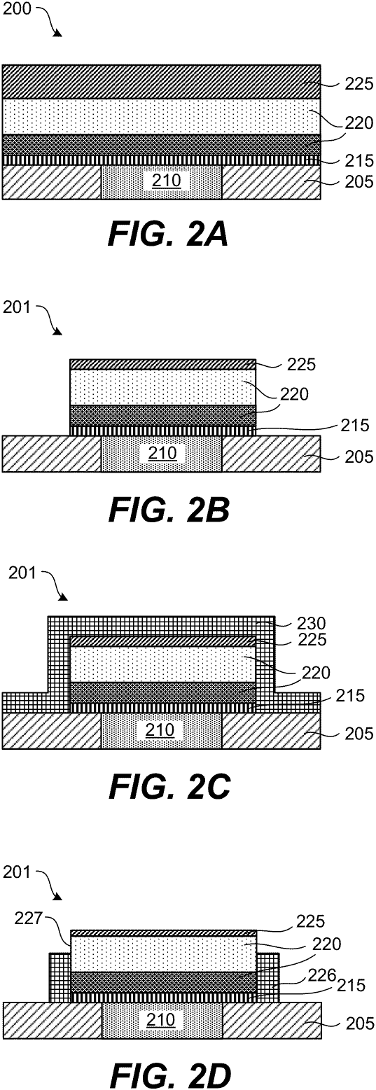

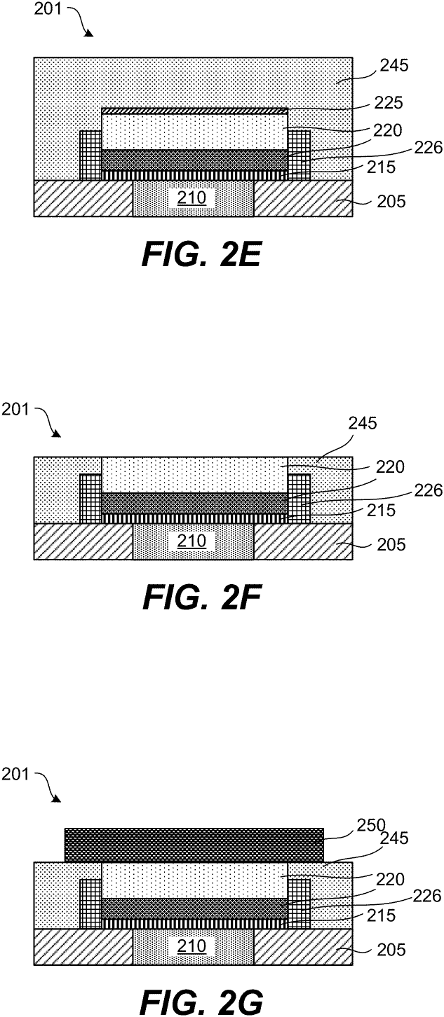

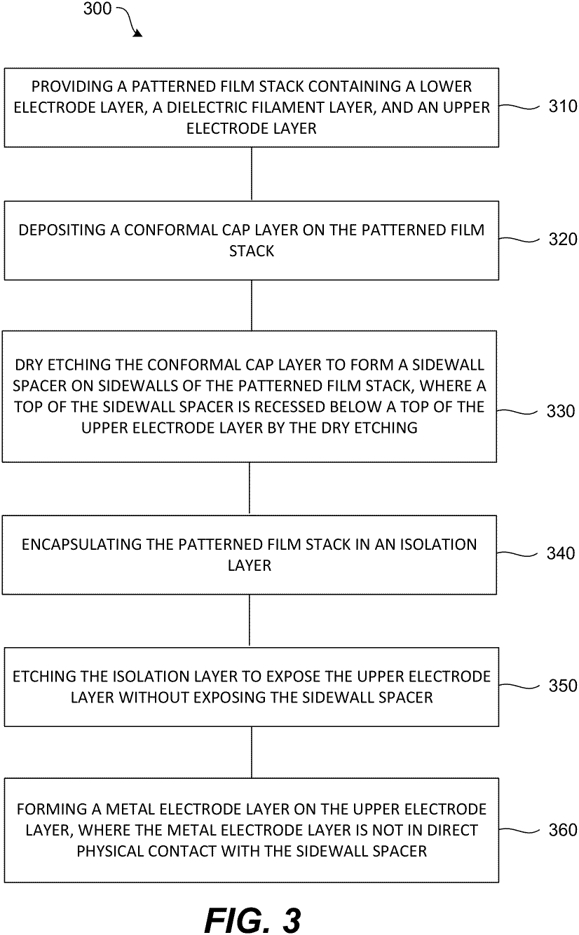

FIGS. 2A — 2G schematically show through cross-sectional views a process flow for manufacturing a resistive memory device according to an embodiment of the invention, and FIG. 3 is a process flow diagram 300 for manufacturing a resistive memory device according to an embodiment of the invention. Unlike the known process described above in the BACKGROUND OF THE INVENTION section, the inventive process flow may be performed under vacuum conditions without exposing the substrate to oxygen-containing species in the processing environment or to air. This provides a controllable processing atmosphere with good control over the amount of oxygen species that are present in the dielectric filament layer and therefore desired switching characteristics of the resistive memory device. Further, the inventive process flow reduces etch damage to material layers in the device, including portions of the material layers that form sidewalls in the patterned film stacks.

FIG. 2A shows a film stack 200 containing a lower electrode layer 210, a dielectric filament layer 215 on the lower electrode layer 210, and an upper electrode layer 220 on the dielectric filament layer 215. As shown in FIG. 2A, the lower electrode layer 210 may be formed in a dielectric film 205. The lower electrode layer 210 can, for example, contain a patterned titanium nitride (TiN) layer in an interlayer dielectric (ILD) film. The patterned film stack 201 further includes a hard mask layer 225 on the upper electrode layer 220. According to one embodiment, the lower electrode layer 210 can include TiN, TaN, W, or laminates thereof. According to one embodiment, the dielectric filament layer 215 can include a high-k metal oxide film, for example HfOₓ, ZrOₓ, TaOₓ, TiOₓ, AlOₓ, or laminates or mixtures thereof. According to one embodiment, the upper electrode layer can contain TiN, TaN, W, or laminates thereof. In a non-limiting example, the upper electrode layer 220 can contain a laminate of TaN on TiN. According to one embodiment, the hard mask layer 225 can include SiN.

In a fully manufactured resistive memory device, the dielectric filament layer 215 operates as a resistively switching material that contains oxygen vacancies which determine the electrical properties of a current conducting filament formed vertically across the dielectric filament layer 215 between the upper electrode layer 220 and the lower electrode layer 210. According to one embodiment, the dielectric filament layer 215 is in direct physical contact with the lower electrode layer 210, and the upper electrode layer 220 is in direct physical contact with the dielectric filament layer 215. The film stack 200 in FIG. 2A may be patterned using conventional photolithography and etching processes. For example, a reactive ion etching (RIE) process may be used for the material removal. The etching may terminate on the dielectric film 205 as depicted in FIG. 2B, where the anisotropic etching process may reduce a vertical thickness of the hard mask layer 225 of the patterned film stack 201.

Thereafter, in 320, and as schematically shown in FIG. 2C, a cap layer 230 is conformally deposited on the vertical and horizontal surfaces of the patterned film stack 201. In one example, the cap layer 230 can contain SiN that is deposited using plasma-enhanced chemical vapor deposition (PECVD) at a substrate temperature between about room temperature and about 200° C.

Thereafter, in 330, and as schematically shown in FIG. 2D, the cap layer 230 is anisotropically etched in a dry etching plasma process. The dry etching processes etches the cap layer 230 from a horizontal top surface of the patterned film stack 201 and from a horizontal surface away from the patterned film stack 201, thereby forming a sidewall spacer 226. According to embodiments of the invention, the sidewall spacer 226 is formed with significant shoulder pulldown of cap layer 230 below the top of the upper electrode layer 220. According to an embodiment of the invention, the shoulder pulldown refers to a distance from the top of the patterned film stack 201 or from the top of the upper electrode layer 220 down to a top of the sidewall spacer 226 on the sidewall 227. The sidewall spacer 226 does not cover the entire sidewall 227 of the patterned film stack 201 and an upper portion of the sidewall 227 is exposed. According to embodiments of the invention, the amount of shoulder pulldown may be controlled by the etch conditions and the duration of the anisotropic etch process. For example, the shoulder pulldown may be increased by increasing the duration of the anisotropic etch process.

According to one embodiment, the anisotropic etching of the cap layer 230 to form the sidewall spacer 226 may be carried out under vacuum conditions where the concentration of oxygen-containing gaseous species is kept very low to reduce or prevent oxidation of the materials of the patterned film stack 201, in particular the dielectric filament layer 215 and adjacent materials layers. In one example, the etching gases do not contain any added oxygen-containing gases, but there may be trace amounts of oxygen-containing background gases (e.g., O₂ and H₂O) in the vacuum environment.

Following the formation of the sidewall spacer 226, the patterned film stack 201 may be further processed to form a resistive memory device. In 340, an isolation layer 245 (e.g., an ILD film) may be deposited such that it encapsulates the patterned film stack 201. This is schematically shown in FIG. 2E. Thereafter, as shown in FIG. 2F, an etching process is performed to etch the isolation layer 245 and expose the top of the upper electrode layer 220 without exposing a top surface of the sidewall spacer 226. As a result, the sidewall spacer 226 is still fully encapsulated by the isolation layer 245 following the etching process. According to one embodiment, the etching process may include a planarization process, for example a chemical mechanical polishing process (CMP).

In 360, the method can further include forming a metal electrode layer 250 on the upper electrode layer. The metal electrode layer 250 may be deposited as a blanked metal-containing film and thereafter patterned using photolithography and etching. As shown in the FIG. 2G, the metal electrode layer 250 is not in direct physical contact with the sidewall spacer 226, as the sidewall spacer 226 is still fully encapsulated by the isolation layer 245 and is spaced away from the metal electrode layer 250.

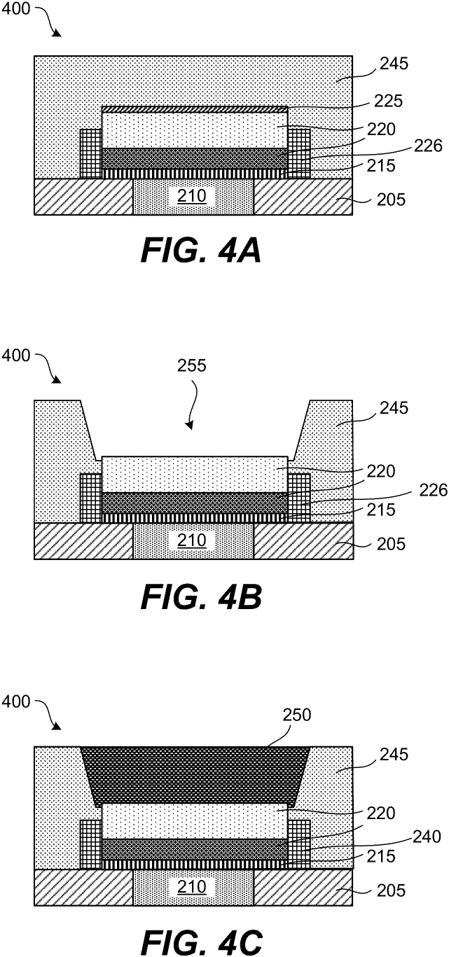

FIGS. 4A — 4C show the formation of a resistive memory device according to another embodiment of the invention. The patterned film stack 201 in FIG. 2E has been reproduced as a patterned film stack 400 in FIG. 4A. The method includes further processing the patterned film stack 201 by forming a via pattern 255 in the isolation layer 245. The via pattern 255 may be formed using photolithography and a dry etching process. The upper electrode layer 220 is exposed during the dry etching process but the sidewall spacer 226 is not exposed. Thus, the sidewall spacer 226 is still fully encapsulated by the isolation layer 245 following the dry etching process. This is schematically shown in FIG. 4B.

Thereafter, as shown in FIG. 4C, a metal electrode layer 250 is formed in the via pattern 255. In one example, a metal-containing layer is deposited to overfill the via pattern 255 and thereafter a CMP process may be performed to remove any metal overburden so that the top of the metal electrode layer 250 and the isolation layer 245 are at least substantially in the same horizontal plane.

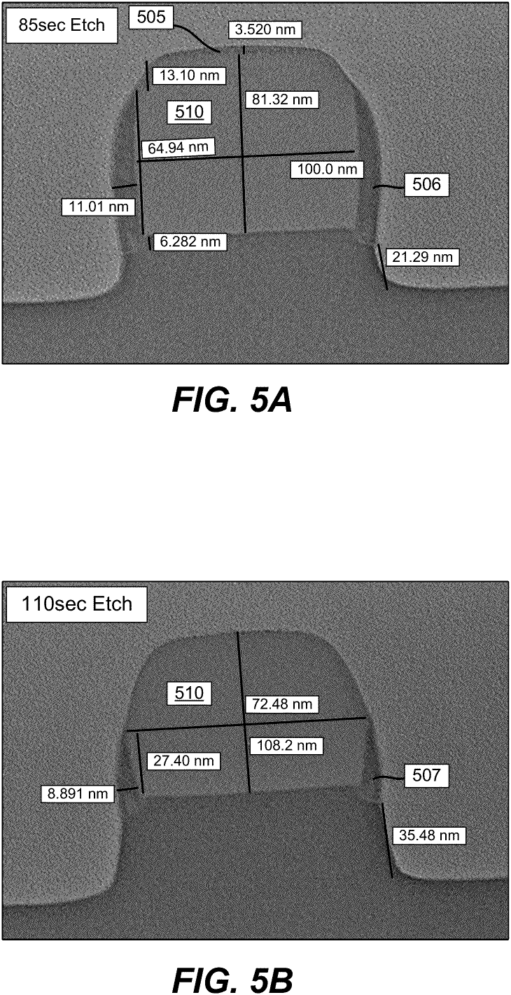

FIGS. 5A and 5B show experimental results for forming a sidewall spacer with different shoulder pulldown according to embodiments of the invention. The figures show cross-sectional transmission electron microscopy (TEM) images of etched test structures. The test structures were prepared to contain a SiOₓ structure 510 and a cap layer 505 with a SiN film that was conformally deposited over the SiOₓ structure 510. FIG. 5A shows a sidewall spacer 506 formed on the sidewalls of the SiOₓ structure 510 following 85 seconds of dry etching using RIE. The cap layer 505 was etched until it was almost completely removed from a top surface of the SiOₓ structure 510 and a top of the sidewall spacer 506 was recessed to about 13 nm below a top of the SiOₓ structure 510. FIG. 5B shows that the cap layer 505 was completely removed from a top surface of the SiOₓ structure 510 and a top of a sidewall spacer 507 was recessed to about 72 nm below a top of the SiOₓ structure 510 following 110 seconds of dry etching using RIE. The results in FIGS. 5A and 5B illustrate that the amount of shoulder pulldown during etching of a cap layer 505 was controlled by the duration of an anisotropic dry etch process, where the amount of shoulder pulldown increased with increasing etch times.

A resistive memory device with an embedded shoulder pulled sidewall spacer and method of forming have been described in several embodiments of the invention. The foregoing description of the embodiments of the invention has been presented for the purposes of illustration and description. It is not intended to be exhaustive or to limit the invention to the precise forms disclosed. This description and the claims following include terms that are used for descriptive purposes only and are not to be construed as limiting. Persons skilled in the relevant art can appreciate that many modifications and variations are possible in light of the above teaching. Persons skilled in the art will recognize various equivalent combinations and substitutions for various components shown in the Figures. It is therefore intended that the scope of the invention be limited not by this detailed description, but rather by the claims appended hereto.

What is claimed is:

1. A method of forming a resistive memory device, the method comprising:
providing a patterned film stack containing a lower electrode layer, a dielectric filament layer on the lower electrode layer, and an upper electrode layer on the dielectric filament layer;
depositing a conformal cap layer on the patterned film stack;
dry etching the conformal cap layer to form a sidewall spacer on sidewalls of the patterned film stack, where a top of the sidewall spacer is recessed to below a top of the upper electrode layer by the dry etching;
encapsulating the patterned film stack in an isolation layer; and
etching the isolation layer to expose the upper electrode layer without exposing the sidewall spacer.

2. The method of claim 1, further comprising:
following the etching, depositing a metal electrode layer on the upper electrode layer, where the metal electrode layer is not in direct physical contact with the sidewall spacer.

3. The method of claim 1, wherein the dry etching removes the conformal cap layer from the top surface of the upper electrode layer.

4. The method of claim 1, wherein the dry etching is performed under vacuum conditions without exposing the patterned film stack to oxygen-containing gaseous species.

5. The method of claim 4, wherein the dry etching includes reactive ion etching (RIE).

6. The method of claim 1, wherein an upper part of the sidewalls is exposed during the dry etching.

7. The method of claim 1, wherein etching the isolation layer includes a planarization process.

8. The method of claim 1, wherein etching the isolation layer includes etching a via pattern in the isolation layer.

9. The method of claim 1, wherein the dielectric filament layer includes a metal oxide.

10. The method of claim 9, wherein the metal oxide contains HfOₓ, ZrOₓ,TaOₓ, TiOₓ, AlOₓ, or a laminate or mixture thereof.

11. The method of claim 1, wherein the lower electrode layer contains TaN, TiN, W, or a laminate thereof.

12. The method of claim 1, wherein the upper electrode layer contains TaN, TiN, W, or a laminate thereof.

13. The method of claim 1, wherein the conformal cap layer and the sidewall spacer include SiN.

14. The method of claim 1, wherein the isolation layer includes an interlayer dielectric (ILD).

15. The method of claim 1, wherein the dielectric filament layer is in direct physical contact with the lower electrode layer, and the upper electrode layer is in direct physical contact with the dielectric filament layer.

16. A resistive memory device comprising:
a patterned film stack containing a lower electrode layer, a dielectric filament layer on the lower electrode layer, and an upper electrode layer on the dielectric filament layer;
a sidewall spacer on sidewalls of the patterned film stack, where a top of the sidewall spacer is recessed to below a top of the upper electrode layer;
an isolation layer that encapsulates the sidewall spacer; and
a metal electrode layer on the upper electrode layer, where the metal electrode layer is not in direct physical contact with the sidewall spacer.

17. The device of claim 16, wherein the dielectric filament layer contains HfOₓ, ZrOₓ,TaOₓ, TiOₓ, AlOₓ, or a laminate or mixture thereof.

18. The device of claim 16, wherein the lower electrode layer contains TaN, TiN, W, or a laminate thereof.

19. The device of claim 16, wherein the upper electrode layer contains TaN, TiN, W, or a laminate thereof.

20. The device of claim 16, wherein the sidewall spacer includes SiN.
